(19) United States
(12) Patent Application Publication
(10) Pub. No.: US 2026/0247590 A1
(43) Pub. Date: Aug. 20, 2026

(54) HEAT SINK WITH INTEGRATED VAPOR CHAMBER FOR SEMICONDUCTOR DEVICE ASSEMBLIES

(71) Applicant: SEMICONDUCTOR COMPONENTS INDUSTRIES, LLC, Scottsdale, AZ (US)

(72) Inventors: Jinseok RYU, Incheon (KR); Sangyun MA, Bucheon (KR)

(73) Assignee: SEMICONDUCTOR COMPONENTS INDUSTRIES, LLC, Scottsdale, AZ (US)

(21) Appl. No.: 19/057,929

(22) Filed: Feb. 19, 2025

(51) Int. Cl. H05K 7/20

(52) U.S. Cl. CPC H05K 7/20936; H05K 7/20436

(57) ABSTRACT

Heat sinks for power electronics assemblies that include liquid cooling jackets. A heat sink may include a vapor chamber. A heat sink may include a baseplate extending from the vapor chamber. A heat sink may include a housing coupled to the baseplate, wherein the housing and the baseplate define an interior volume configured for a first working fluid to pass therethrough to transfer thermal energy from the baseplate and the vapor chamber to the first working fluid.

### TECHNICAL FIELD

This description relates to semiconductor device assemblies. More specifically, this description relates to heat sinks for dissipating heat from power device modules of semiconductor device assemblies.

### BACKGROUND

Semiconductor device assemblies, such as assemblies including power semiconductor devices (which can be referred to as power modules, multi-chip power modules, etc.), can be implemented using semiconductor die, substrates (e.g., direct-bonded metal substrates, ceramic substrates, and so forth), wire bonds, etc. Such semiconductor device assemblies can be coupled with one or more heat sinks for dissipating heat generated by the semiconductor devices during operation.

### SUMMARY

In some aspects, the techniques described herein relate to a heat sink, including: a vapor chamber; a baseplate extending from the vapor chamber; and a housing coupled to the baseplate; wherein the housing and the baseplate define an interior volume configured for a first working fluid to pass therethrough to transfer thermal energy from the baseplate and the vapor chamber to the first working fluid.

In some aspects, the techniques described herein relate to a heat sink, wherein the vapor chamber includes an upper wall and a lower wall that define a sealed chamber that contains a second working fluid, wherein the upper wall is configured to be coupled to a power device module and the lower wall partially defines the interior volume and comes into direct contact with the first working fluid.

In some aspects, the techniques described herein relate to a heat sink, wherein the baseplate is joined to the vapor chamber at a perimeter of the vapor chamber.

In some aspects, the techniques described herein relate to a heat sink, wherein the baseplate includes an opening, wherein the vapor chamber is disposed in the opening and coupled to the baseplate.

In some aspects, the techniques described herein relate to a heat sink, wherein a thickness of the baseplate is substantially the same as a height of the vapor chamber.

In some aspects, the techniques described herein relate to a heat sink, further including a vapor chamber pin fin array extending from the lower wall of the vapor chamber.

In some aspects, the techniques described herein relate to a heat sink, further including a baseplate pin fin array extending from a lower surface of the baseplate, wherein at least one characteristic of the vapor chamber pin fin array is different than the baseplate pin fin array.

In some aspects, the techniques described herein relate to a heat sink, wherein the at least one characteristic is a length, a cross-sectional area, a thermal conductivity, or a pin-to-pin spacing.

In some aspects, the techniques described herein relate to a heat sink, further including a baseplate pin fin array extending from a lower surface of the baseplate, wherein a pin fin of the baseplate pin fin array is shorter than a pin fin of the vapor chamber pin fin array and defines a bypass flowpath between the baseplate pin fins and an inner wall of the housing.

In some aspects, the techniques described herein relate to a power electronics assembly, including: at least one power device module; and a heat sink including: a vapor chamber; a baseplate extending from the vapor chamber; and a housing coupled to the baseplate; wherein the housing and the baseplate define an interior volume configured for a first working fluid to pass therethrough to transfer thermal energy from the baseplate and the vapor chamber to the first working fluid.

In some aspects, the techniques described herein relate to a power electronics assembly, wherein the vapor chamber includes an upper wall and a lower wall that define a sealed chamber that contains a second working fluid, wherein the upper wall is coupled to the at least one power device module and the lower wall partially defines the interior volume and comes into direct contact with the first working fluid.

In some aspects, the techniques described herein relate to a power electronics assembly, wherein the at least one power device module includes a direct bonded metal (DBM) substrate that includes a metal layer, wherein the upper wall of the vapor chamber is directly coupled to the metal layer of the DBM substrate.

In some aspects, the techniques described herein relate to a power electronics assembly, wherein the baseplate is joined to the vapor chamber at a perimeter of the vapor chamber.

In some aspects, the techniques described herein relate to a power electronics assembly, wherein the baseplate includes an opening, wherein the vapor chamber is disposed in the opening and coupled to the baseplate.

In some aspects, the techniques described herein relate to a power electronics assembly, wherein a thickness of the baseplate is substantially the same as a height of the vapor chamber.

In some aspects, the techniques described herein relate to a power electronics assembly, further including a vapor chamber pin fin array extending from the lower wall of the vapor chamber.

In some aspects, the techniques described herein relate to a power electronics assembly, further including a baseplate pin fin array extending from a lower surface of the baseplate, wherein at least one characteristic of the vapor chamber pin fin array is different than the baseplate pin fin array.

In some aspects, the techniques described herein relate to a power electronics assembly, wherein the at least one characteristic is a length, a cross-sectional area, a thermal conductivity, or a pin-to-pin spacing.

In some aspects, the techniques described herein relate to a power electronics assembly, further including a baseplate pin fin array extending from a lower surface of the baseplate, wherein a pin fin of the baseplate pin fin array is shorter than a pin fin of the vapor chamber pin fin array and defines a bypass flowpath between the baseplate pin fin array and an inner wall of the housing.

In some aspects, the techniques described herein relate to a power electronics assembly, wherein the at least one power device module includes a first power device module and a second power device module, wherein the first power device module and the second power device module are coupled to the upper wall of the vapor chamber.

In some aspects, the techniques described herein relate to a power electronics assembly, further including a pin fin array extending from the lower wall of the vapor chamber, wherein the pin fin array includes a first section of pin fins aligned with the first power device module, a second section of pin fins aligned with the second power device module, and a third section of pin fins located between the first and second sections of pin fins, wherein at least one characteristic of the third section of pin fins is different than at least one of the first or second sections of pin fins.

### BRIEF DESCRIPTION OF THE DRAWINGS

FIG. 1 is a cross-sectional side view of an example power electronics assembly.

FIG. 2A is a cross-sectional side view of an example power electronics assembly.

FIG. 2B is a cross-sectional side view of the heat sink of the example power electronics assembly of FIG. 2A.

FIG. 2C is a top view of the heat sink of FIG. 2B.

FIG. 3 is a cross-sectional side view of an example heat sink.

FIG. 4A is a cross-sectional side view of an example power electronics assembly.

FIG. 4B is a cross-sectional side view of the heat sink of the example power electronics assembly of FIG. 4A.

FIG. 5A is a cross-sectional side view of an example power electronics assembly.

FIG. 5B is a cross-sectional side view of the heat sink of the example power electronics assembly of FIG. 5A.

FIG. 6A is a cross-sectional side view of an example power electronics assembly.

FIG. 6B is a cross-sectional side view of the heat sink of the example power electronics assembly of FIG. 6A.

FIG. 7A is a cross-sectional side view of an example power electronics assembly.

FIG. 7B is a cross-sectional side view of the heat sink of the example power electronics assembly of FIG. 7A.

In the drawings, which are not necessarily drawn to scale, like reference symbols may indicate like and/or similar components (elements, structures, etc.) in different views. The drawings illustrate generally, by way of example, but not by way of limitation, various implementations discussed in the present disclosure. Reference symbols shown in one drawing may not be repeated for the same, and/or similar elements in related views. Reference symbols that are repeated in multiple drawings may not be specifically discussed with respect to each of those drawings, but are provided for context between related views. Also, not all like elements in the drawings are specifically referenced with a reference symbol when multiple instances of an element are illustrated.

### DETAILED DESCRIPTION

Semiconductor device assemblies for use in power electronics generate a significant amount of heat during operation. The heat generated by the devices is dissipated by one or more heat sinks so that operating temperatures of the semiconductor devices remain below allowable temperature limits. Aspects of the present disclosure include heat sinks that include liquid cooling jackets to increase the rate of heat transfer from the devices. The liquid cooling jackets can include a baseplate coupled to a housing in which a liquid coolant, also referred to herein as a working fluid, flows. Aspects of the present disclosure also include vapor chambers which can further improve heat transfer and thermal performance. A vapor chamber is a phase change cooling component in which a coolant undergoes a cyclic phase change during the heat transfer process, which results in greater heat absorption and dissipation as compared to a single-phase heat transfer process. Aspects of the present disclosure include heat sinks that include liquid cooling jackets with integrated vapor chambers that provide for the direct cooling of a semiconductor device by a vapor chamber and may also include the direct cooling of the vapor chamber by the liquid cooling jacket. A liquid cooling jacket with an integrated vapor chamber can provide an improved thermal dissipation performance and the vapor chamber can provide a relatively small form factor relative to the thermal performance benefit.

A power device module can include at least one substrate (e.g., a power electronic substrate such as a direct bonded metal (DBM) substrate) on which circuit components and devices (e.g., insulated-gate bipolar transistor (IGBT) power devices, fast recovery diodes (FRDs), silicon carbide metal-oxide-semiconductor field-effect transistors (SiC MOSFETs), silicon (Si) MOSFETs), metal-oxide high-voltage DC line capacitors, main circuit bus bars, a power device module drive circuit board, a motor control circuit board, three-phase current sensors, and DC and heavy-current AC connectors, etc.) are attached (e.g., soldered). A power device module can be held, e.g., packaged in a casing or housing.

In some implementations, one or more semiconductor die (e.g., one or more semiconductor components) can be, or can include, a power semiconductor die. In some implementations, one or more semiconductor die can be (e.g., can be a portion of), or can include, one or more of a MOSFET device, an IGBT, an integrated circuit (IC), an inverter, a power conversion circuit, a bridge circuit, a FRD, a diode, and/or so forth. In some implementations, one or more semiconductor die can be (e.g., can be a portion of), or can include, a component for an electrical vehicle (EV).

The components and devices may be attached as semiconductor dies (integrated circuit chips) on a top surface of the DBM substrate. The top surface of the DBM substrate may include metal traces and conductive pads to electrically connect the components and devices. For example, a pad on a semiconductor die of a component may be wire bonded to a metal trace on the substrate, which, in turn, may be welded to a lead frame or terminal finger providing an external connection terminal to the package. Pins (e.g., signal pins) may also be attached (e.g., soldered) to the traces on the substrate to provide external connection points to the circuit components and devices.

The package casing (e.g., of a single-side cooling (SSC) power device module) may include a cover portion affixed (e.g., epoxied) to a base portion so that the substrate and the components are contained within a cavity (an interior volume) defined by the base portion and the cover portion. The cover portion of the casing, opposite to the base portion, may include holes through which the pins (e.g., soldered signal pins) can extend to the outside of the package to provide exterior connection points to the components and circuitry contained within the casing. The package casing and its cover portion may be made of plastic or polymer materials.

In an SSC power device module, cooling may be achieved by thermal radiation from an outer surface of the substrate. In a dual-side cooling (DSC) power device module, the semiconductor dies (which may be attached to spacer blocks) are disposed between two substrates (e.g., a top DBM substrate and a bottom DBM substrate) in the package casing. In some example implementations, the semiconductor die (which may be attached to a spacer block) may be disposed between the bottom DBM substrate and a conductive strip of material (e.g., a copper clip, an aluminum clip, etc.). In a DSC power device module, cooling may be achieved by, and limited to, radiation emitting from the outer surfaces of the two DBM substrates (or conductive strips of material, e.g., a metal clip).

In some implementations, a heat sink (e.g., a baseplate, a fin array, a pin-fin array, and/or a liquid cooling jacket) can help draw away, transfer, or dissipate the heat generated by the power device modules. The heat sink may be coupled to, for example, a bottom side of a DBM substrate.

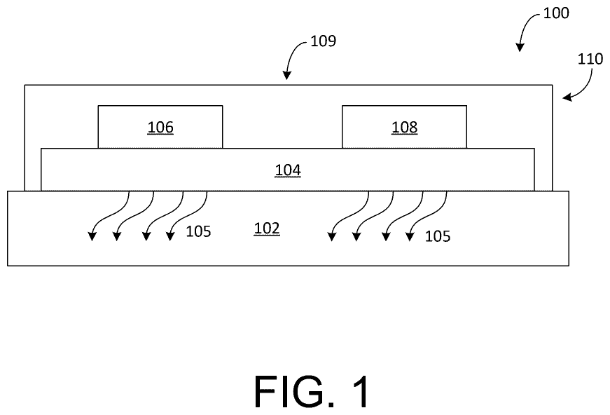

FIG. 1 is a schematic cross-sectional side view of an example power electronics assembly 100 which includes an SSC power device module 110 and a heat sink 102 coupled to a bottom side thereof for transferring or dissipating thermal energy 105 generated by the power device module 110. The power device module 110 may include a DBM substrate 104 (e.g. a direct bond copper (DBC) substrate) on which power devices (e.g., power devices 106, 108) are disposed. The DBM substrate 104 and power devices 106, 108 may be disposed in a casing 109. The power devices may be any type of power device, including any disclosed herein, such as an IGBT, MOSFET, or diode, etc. In some examples, the power device module 110 may include one or more additional layers for electrically, mechanically, and/or thermally coupling the components, such as a heat spreader (not illustrated) located, e.g., between the DBM substrate 104 and the heat sink 102 and/or solder layers and/or thermal grease layers. The heat sink may include one or more features for

[symbol]

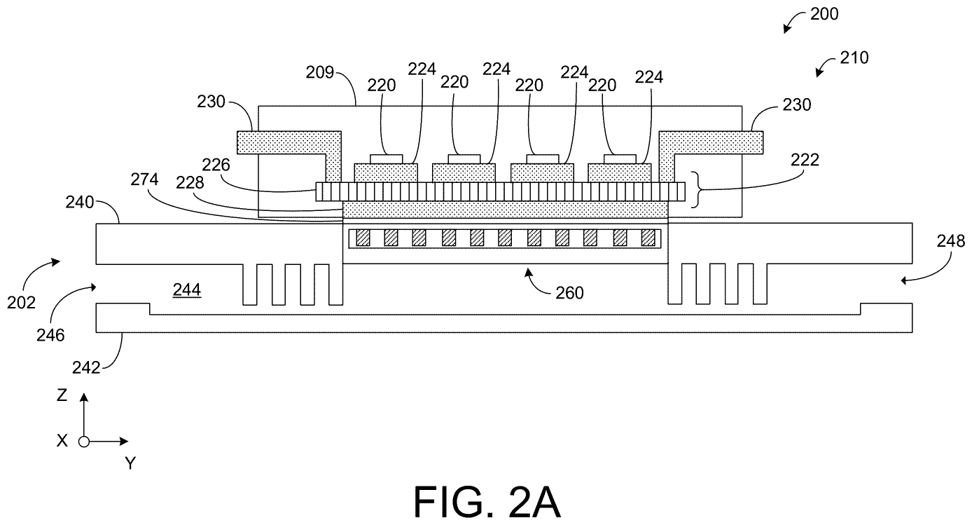

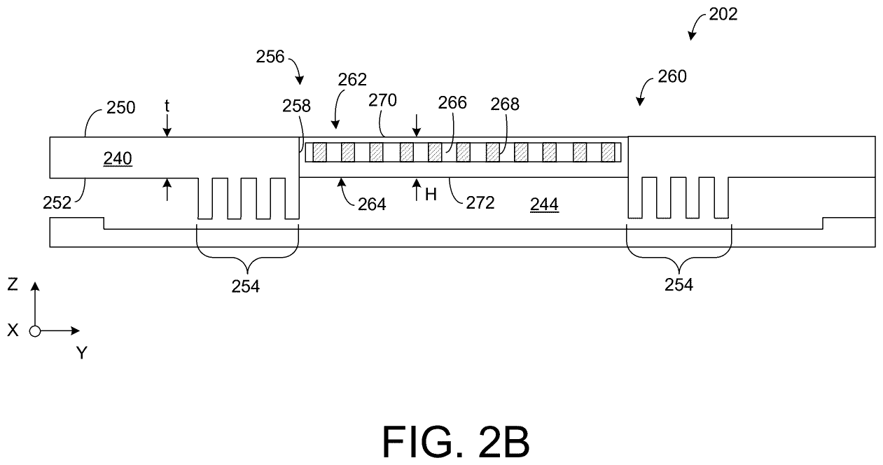

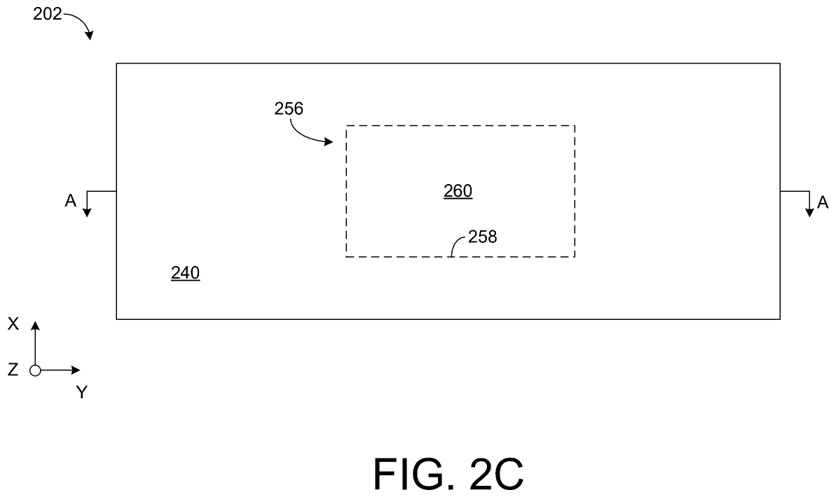

FIG. 2A is a cross-sectional side view of an example implementation of a power electronics assembly 200 that includes a power device module 210 coupled to a heat sink 202. FIG. 2B is a cross-sectional side view of the heat sink 202 taken along line A-A of FIG. 2C., and FIG. 2C is a top view of the heat sink 202.

Referring to FIGS. 2A-2C, in the illustrated example power device module 210 is disposed in a casing 209. The power device module 210 includes a plurality, e.g., four semiconductor die 220 disposed on a substrate, e.g., a DBM substrate 222, where the DBM substrate includes an upper metal layer 224, an insulator layer 226, and a lower metal layer 228. Pins 230 extend from the power device module 210 for electrical connection of the power device module to other components.

In the illustrated example, the heat sink 202 is a liquid cooled heat sink that includes a baseplate 240 that is coupled to a housing 242. The baseplate 240 and housing 242 define an interior volume 244 that is configured for a first working fluid, such as, for example, a water-ethylene glycol mixture, to pass therethrough to transfer thermal energy from the power device module 210 to the first working fluid. The heat sink 202 also includes a working-fluid inlet 246 and a working-fluid outlet 248 for transfer of the first working fluid into and out of the heat sink. The baseplate 240 has an upper surface 250 and a lower surface 252 and in the illustrated example, at least one pin fin array 254 is coupled to and extends from the lower surface 252 of the baseplate. The pin fin array 254 and the baseplate 240 may be a unitary member, for example the pin fin array 254 may be formed by removing material, e.g., machining a lower surface of the baseplate. In an example the pin fin array 254 may be formed by joining the pin fins to the baseplate 240 by a joining process, such as welding, brazing or soldering.

In the illustrated example, the heat sink 202 also includes a vapor chamber 260 that is coupled to the power device module 210 and the baseplate 240 for transferring thermal energy from the power device module to the first working fluid in the interior volume 244. In an example, the vapor chamber 260 includes an upper wall 262 and a lower wall 264 that define a sealed chamber 266 that contains a second working fluid, such as water. The vapor chamber 260 may also include a plurality of spacers 268, such as metal columns, that structurally support and separate the upper wall 262 and lower wall 264. The vapor chamber 260 may be formed from one or more materials, such as Al, AlSiC, Cu, and/or other materials.

In an example, the baseplate 240 is mechanically attached, e.g., by brazing or friction stir welding, to the vapor chamber 260. For example, the baseplate 240 may have an opening 256 having a shape or dimension that is complementary to a shape or dimension of the vapor chamber 260 and the vapor chamber 260 may be disposed in the opening in the baseplate. An inner wall 258 of the baseplate that defines the opening 256 may be mechanically attached to an outer extent or outer perimeter of the vapor chamber 260, for example, by brazing or friction stir weld.

In an example, the vapor chamber 260 may be disposed in the baseplate 240, in an example, the baseplate 240 may extend from the vapor chamber 260. In an example, the lower wall 264 of the vapor chamber 260 may partially define the interior volume 244 of the heat sink 202 and may come into direct contact with the first working fluid. As shown in, e.g., FIG. 2B, the baseplate 240 may have a thickness, t, extending between the upper surface 250 and the lower surface 252 of the baseplate. The vapor chamber 260 may have a height, H, extending between the upper wall 262 and the lower wall 264 of the vapor chamber. In an example, the thickness, t, of the baseplate 240 may be substantially the same as, or approximately equal to, the height, H, of the vapor chamber 260. In an example, the upper surface 250 of the baseplate 240 may be substantially aligned with an upper surface 270 of the upper wall 262 of the vapor chamber 260. In an example, the lower surface 252 of the baseplate 240 may be substantially aligned with a lower surface 272 of the lower wall 264 of the vapor chamber 260. In an example the thickness, t, of the baseplate 240 may be different than the height, H, of the vapor chamber 260. In an example, the upper surface 270 of the upper wall 262 and/or the lower surface 272 of the lower wall 264 of the vapor chamber 260 may be offset from, e.g., may be recessed with respect to, or stand proud of, the upper surface 250 and/or the lower surface 252 of the baseplate 240.

The vapor chamber 260 may be configured to be attached, e.g., directly attached to a power device module such as example power device module 210. As shown in FIG. 2A, in an example, the upper wall 262 of the vapor chamber 260 is coupled to the lower metal layer 228 of the DBM substrate 222, for example, by a solder layer 274. In some examples, the DBM substrate 222 may be directly coupled to the vapor chamber 260 by welding, brazing, soldering, and/or thermally coupled by a thermal interface material. In some examples an additional layer, e.g., an additional metal layer, may be disposed between the DBM substrate 222 and the vapor chamber 260.

The vapor chamber 260 includes the upper wall 262 and the lower wall 264 that define the sealed chamber 266 that contains the second working fluid. The vapor chamber 260 is a phase changing cooling component where the second working fluid continuously undergoes a phase change during a heat transfer process. For example, the sealed chamber 266 may be a vacuum-sealed chamber and the vapor chamber 260 may contain a wick structure, e.g., a sintered, grooved, or mesh wick structure (not illustrated) that lines interior surfaces of the sealed chamber 266. The wick structure may contain, e.g., be saturated with, the second working fluid. A portion of the second working fluid located adjacent the inner surface of the upper wall 262 may be configured to extract heat from the power device module 210 coupled to the upper wall of the vapor chamber. The extracted heat may cause the second working fluid to undergo a phase change, transitioning the second working fluid from a liquid phase to a vapor phase, thereby causing a mass transfer of the second working fluid from the wick structure of the upper wall 262 to the interior space of the sealed chamber 266. The vapor-state working fluid may then move towards and contact the relatively-cooler lower wall 264, which may be at a lower temperature than the upper wall 262. The relatively lower temperature of the lower wall 264 causes the second working fluid to condense from the vapor phase back to a liquid phase, also resulting in a transfer of thermal energy, e.g., the latent heat of vaporization of the second working fluid, to the lower wall 264. The released thermal energy may then be transferred through the lower wall 264 to the first working fluid in the interior volume 244 of the heat sink 202. The condensed second working fluid on the lower wall 264 of the sealed chamber 266 can then return to the inner surface of the upper wall 262, e.g., by capillary action through the wick structure, to be vaporized again by the heat dissipated from the power device module 210.

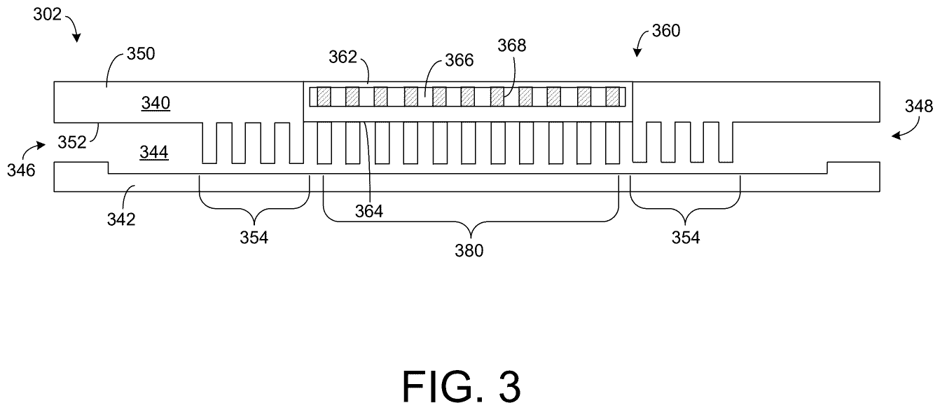

FIG. 3 is a cross-sectional side view of a heat sink 302 that is substantially the same as heat sink 202 (FIGS. 2A-2C). Heat sink 302 differs from heat sink 202 in that a pin fin array 380 extends from a lower wall 364 of the vapor chamber 360.

Heat sink 302 is a liquid cooled heat sink that includes a baseplate 340 that is coupled to a housing 342. The baseplate 340 and housing 342 define an interior volume 344 that is configured for a first working fluid, such as, for example, a water-ethylene glycol mixture, to pass therethrough to transfer thermal energy from a power device module, such as power device module 210 (FIG. 2A) to the first working fluid. The heat sink 302 also includes a working-fluid inlet 346 and a working-fluid outlet 348 for transfer of the first working fluid into and out of the heat sink. The baseplate 340 has an upper surface 350 and a lower surface 352 and in the illustrated example, at least one pin fin array 354 is coupled to and extends from the lower surface 352 of the baseplate. The pin fin array 354 and the baseplate 340 may be a unitary member, for example the pin fin array 354 may be formed by removing material, e.g., machining a lower surface of the baseplate. In an example the pin fin array 354 may be formed by joining the pin fins to the baseplate 340 by a joining process, such as welding, brazing or soldering.

In the illustrated example, the heat sink 302 also includes a vapor chamber 360 that is configured to be coupled to a power device module such as power device module 210. In an example, the vapor chamber 360 includes an upper wall 362 and a lower wall 364 that define a sealed chamber 366 that contains a second working fluid, such as water. The vapor chamber 360 may also include a plurality of spacers 368, such as metal columns, that structurally support and separate the upper wall 362 and lower wall 364. In an example, the baseplate 340 is mechanically attached, e.g., by brazing or friction stir welding, to the vapor chamber 360.

Unlike vapor chamber 260 (FIGS. 2A-2C), the vapor chamber 360 may include a pin fin array 380 that extends from the lower wall 364 of the vapor chamber. The pin fin array 380 and the lower wall 364 may be a unitary member, for example the pin fin array 380 may be formed by removing material, e.g., machining a lower surface of the lower wall 364. In an example the pin fin array 380 may be formed by joining the pin fins to the lower wall 364 by a joining process, such as welding, brazing or soldering. A length, cross sectional shape, and/or cross-sectional size of the pin fins of the pin fin array 380 and the at least one pin fin array 354 may be the same or may be different.

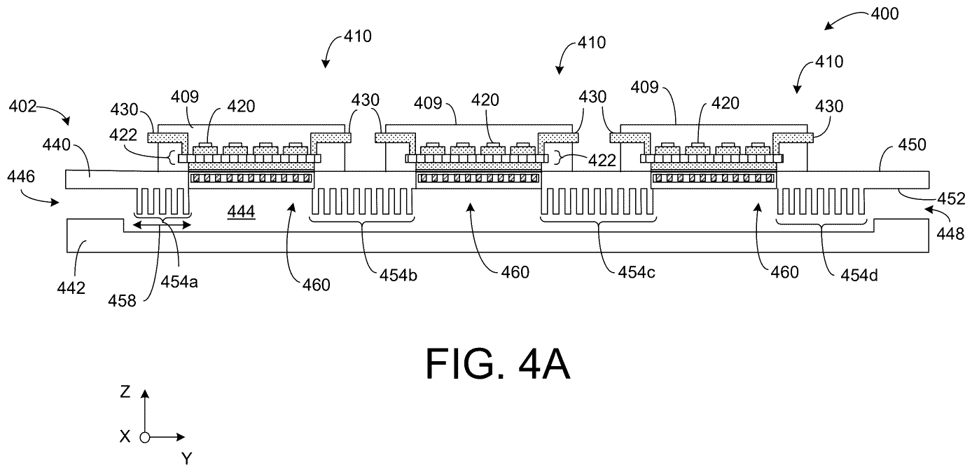

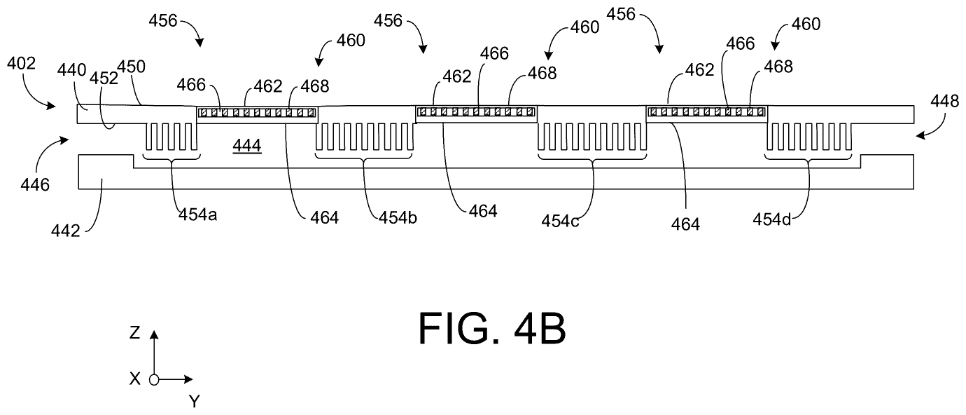

FIG. 4A is a cross-sectional side view of an example implementation of a power electronics assembly 400 that includes a plurality, e.g., three power device modules 410 coupled to a heat sink 402. FIG. 4B is a cross-sectional side view of the heat sink 402 of the power electronics assembly 400.

Referring to FIGS. 4A and 4B, in the illustrated example, the power device modules 410 are each disposed in a casing 409 and include a plurality, e.g., four, semiconductor die 420 (only one labeled) disposed on a substrate, e.g., a DBM substrate 422. Pins 430 extend from the power device modules 410 for electrical connection of a power device module to other components.

In the illustrated example, the heat sink 402 is a liquid cooled heat sink that includes a baseplate 440 that is coupled to a housing 442. The baseplate 440 and housing 442 define an interior volume 444 that is configured for a first working fluid, such as, for example, a water-ethylene glycol mixture, to pass therethrough to transfer thermal energy from the power device modules 410 to the first working fluid. The heat sink 402 also includes a working-fluid inlet 446 and a working-fluid outlet 448 for transfer of the first working fluid into and out of the heat sink.

The baseplate 440 has an upper surface 450 and a lower surface 452 and in the illustrated example, at least one pin fin array 454 is coupled to and extends from the lower surface 452 of the baseplate. The pin fin array 454 and the baseplate 440 may be a unitary member, for example the pin fin array 454 may be formed by removing material, e.g., machining, a lower surface of the baseplate. In an example the pin fin array 454 may be formed by joining the pin fins to the baseplate 440 by a joining process, such as welding, brazing or soldering.

The pin fin array 454 may have a plurality of characteristics, including, for example, a cross-sectional shape (e.g., diamond, circle, oval, oblong, triangle, etc.), a cross-sectional size, a material type, a thermal conductivity, and a pin-to-pin spacing. Characteristics of the pin fin array 454 may also include a length of the pin fins and a corresponding space or gap between an end of the pin fins and an inner wall of the housing 442. The space or gap between ends of the pin array 454 and the inner wall of the housing 442 forms a bypass flowpath 458, which allows a portion of the first working fluid to bypass the corresponding pin fins. The pin fin array 454 may include one or more sections, for example, a plurality of sections 454a, 454b, 454c and 454d. One or more sections, e.g., sections 454b and 454c, may be located between ones of the vapor chambers 460 and sections 454a and 454d may be located between a vapor chamber 460 and the working-fluid inlet 446 or working-fluid outlet 448.

Any one or more characteristics of a given one of the sections of the pin fin arrays 454 may be different than another one of the sections of the pin fin arrays 454. For example, a cross-sectional shape, a cross sectional size, a material type, a thermal conductivity, a pin-to-pin spacing, or a pin fin length of a pin-fin array section located between vapor chambers, e.g., pin-fin-array section 454b or 454c may be different than a pin-fin array section located between the working-fluid inlet 446 or working-fluid outlet 448 and a vapor chamber 460, e.g., pin-fin-array section 454a or 454d. By way of non-limiting example, a length or pin-to-pin spacing of pin-fin-array section 454a or 454d may be different than pin-fin-array section 454b or 454c.

In the illustrated example, the heat sink 402 also includes at least one vapor chamber 460 that is coupled to at least one of the power device modules 410 and the baseplate 440 for transferring thermal energy from the corresponding power device module to the first working fluid in the interior volume 444. In the illustrated example, power electronics assembly 400 includes a plurality of vapor chambers 460, e.g., a number of vapor chambers 460 that corresponds to a number of power device modules 410 of the power electronics assembly 400. For purposes of illustration, example power electronics assembly 400 includes three power device modules 410 and three vapor chambers 460. As will be appreciated, the number of power device modules and vapor chambers that may be coupled to a heat sink, such as heat sink 402, may vary according to an application. For example, a number of power device modules and vapor chambers of a power electronics assembly of the present disclosure may be in the range of 1 power device module and 1 vapor chamber to approximately 50 power device modules and 50 vapor chambers and any integer number therebetween. A number of power device modules may also be greater or less than a number of vapor chambers, for example, one or more vapor chambers may be coupled to a corresponding two or more power device modules.

In an example, the vapor chambers 460 include an upper wall 462 and a lower wall 464 that define a sealed chamber 466 that contains a second working fluid, such as water. The vapor chamber 460 may also include a plurality of spacers 468, such as metal columns, that structurally support and separate the upper wall 462 and lower wall 464. The vapor chamber 460 may be formed from one or more materials, such as Al, AlSiC, Cu, and/or other materials.

In an example, the baseplate 440 is mechanically attached, e.g., by brazing or friction stir welding, to each of the vapor chambers 460. For example, the baseplate 440 may have at least one opening 456 having a shape or dimension that is complementary to a shape or dimension of a corresponding vapor chamber 460 disposed in the opening. In the illustrated example, baseplate 440 includes three openings 456, with a vapor chamber 460 disposed in each opening. An inner wall of the baseplate that defines the opening 456 may be mechanically attached to an outer extent or outer perimeter of the corresponding vapor chamber 460, for example, by brazing or friction stir weld.

In an example, the vapor chambers 460 may be disposed in the baseplate 440, in an example, the baseplate 440 may extend from the vapor chambers 460. In an example, the lower walls 464 of the vapor chambers 460 may each partially define the interior volume 444 of the heat sink 402 and may come into direct contact with the first working fluid. The baseplate 440 may have a thickness extending between the upper surface 450 and the lower surface 452 of the baseplate. The vapor chamber 460 may have a height extending between the upper wall 462 and the lower wall 464 of the vapor chamber. In an example, the thickness of the baseplate 440 may be substantially the same as, or approximately equal to, the height of one or more of the vapor chambers 460. In an example, the upper surface 450 of the baseplate 440 may be substantially aligned with an upper surface of the upper wall 462 of one or more of the vapor chambers 460. In an example, the lower surface 452 of the baseplate 440 may be substantially aligned with a lower surface of the lower wall 464 of one or more of the vapor chambers 460. In an example, the thickness of the baseplate 440 may be different than the height of one or more of the vapor chambers 460. In an example, the upper surface of the upper wall 462 and/or the lower surface of the lower wall 464 of one or more of the vapor chambers 460 may be offset from, e.g., may be recessed with respect to, or stand proud of, the upper surface 450 and/or the lower surface 452 of the baseplate 440.

The vapor chamber 460 may be configured to be attached, e.g., directly attached to, a power device module such as one of example power device modules 410. In an example, the upper wall 462 of a given vapor chamber 460 may be coupled to a lower metal layer of a corresponding one of the DBM substrates 422, for example, by a solder layer. In some examples, the DBM substrates 422 may be directly coupled to a corresponding one of the vapor chambers 460 by welding, brazing, soldering, and/or thermally coupled by a thermal interface material. In some examples an additional layer, e.g., an additional metal layer, may be disposed between one or more of the DBM substrates 422 and a corresponding one of the vapor chambers 460.

At least one of the vapor chambers 460 may include the upper wall 462 and the lower wall 464 that define the sealed chamber 466 that contains the second working fluid. The vapor chambers 460 are phase changing cooling components where the second working fluid continuously undergoes a phase change during a heat transfer process. For example, the sealed chamber 466 may be a vacuum-sealed chamber and the vapor chamber 460 may contain a wick structure, e.g., a sintered, grooved, or mesh wick structure (not illustrated) that lines interior surfaces of the sealed chamber 466. The wick structure may contain, e.g., be saturated with, the second working fluid. A portion of the second working fluid located adjacent the inner surface of the upper wall 462 may be configured to extract heat from a given power device module 410 coupled to the upper wall of the vapor chamber. The extracted heat may cause the second working fluid to undergo a phase change, transitioning the second working fluid from a liquid phase to a vapor phase, thereby causing a mass transfer of the second working fluid from the wick structure of the upper wall 462 to the interior space of the sealed chamber 466. The vapor-state working fluid may then move towards and contact the relatively-cooler lower wall 464, which may be at a lower temperature than the upper wall 462. The relatively lower temperature of the lower wall 464 causes the second working fluid to condense from the vapor phase back to a liquid phase, also resulting in a transfer of thermal energy, e.g., the latent heat of vaporization of the second working fluid, to the lower wall 464. The released thermal energy may then be transferred through the lower wall 464 to the first working fluid in the interior volume 444 of the heat sink 402. The condensed second working fluid on the lower wall 464 of the sealed chamber 466 can then return to the inner surface of the upper wall 462, e.g., by capillary action through the wick structure, to be vaporized again by the heat dissipated from the power device module 410.

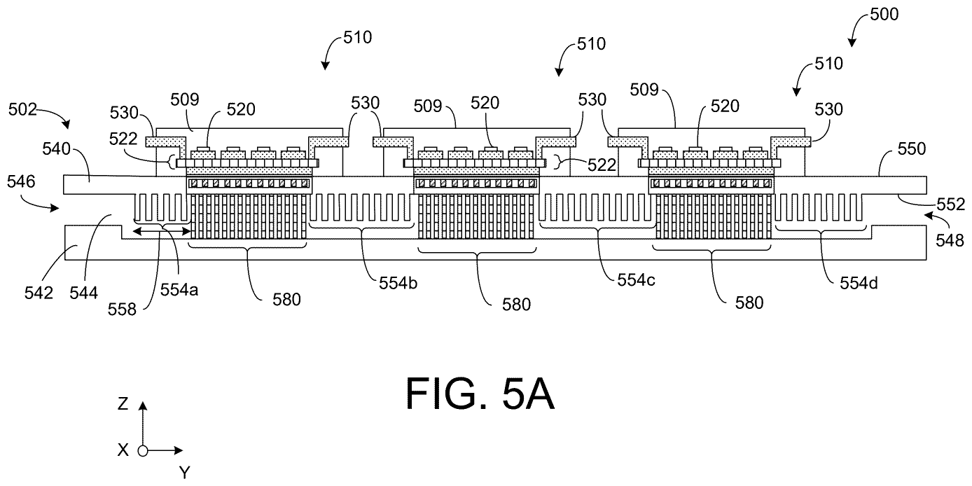

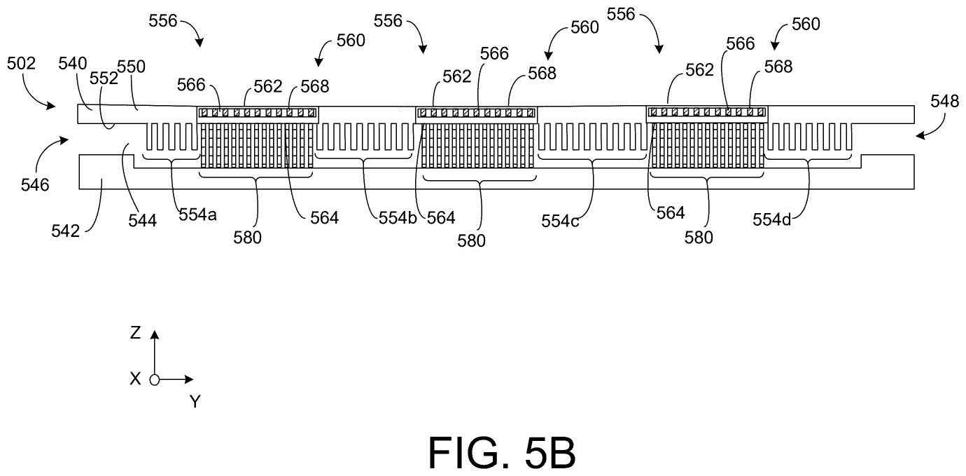

FIG. 5A is a cross-sectional side view of an example implementation of a power electronics assembly 500 that includes a plurality, e.g., three power device modules 510 coupled to a heat sink 502. FIG. 5B is a cross-sectional side view of the heat sink 502 of the power electronics assembly 500.

Referring to FIGS. 5A and 5B, in the illustrated example, the power device modules 510 are each disposed in a casing 509 and include a plurality, e.g., four, semiconductor die 520 (only one labeled) disposed on a substrate, e.g., a DBM substrate 522. Pins 530 extend from the power device modules 510 for electrical connection of a power device module to other components.

In the illustrated example, the heat sink 502 is a liquid cooled heat sink that includes a baseplate 540 that is coupled to a housing 542. The baseplate 540 and housing 542 define an interior volume 544 that is configured for a first working fluid, such as, for example, a water-ethylene glycol mixture, to pass therethrough to transfer thermal energy from the power device modules 510 to the first working fluid. The heat sink 502 also includes a working-fluid inlet 546 and a working-fluid outlet 548 for transfer of the first working fluid into and out of the heat sink.

In the illustrated example, the heat sink 502 also includes at least one vapor chamber 560 that is coupled to at least one of the power device modules 510 and the baseplate 540 for transferring thermal energy from the corresponding power device module to the first working fluid in the interior volume 544. In the illustrated example, power electronics assembly 500 includes a plurality of vapor chambers 560, e.g., a number of vapor chambers 560 that corresponds to a number of power device modules 510 of the power electronics assembly 500. For purposes of illustration, example power electronics assembly 500 includes three power device modules 510 and three vapor chambers 560. As will be appreciated, the number of power device modules and vapor chambers that may be coupled to a heat sink, such as heat sink 502, may vary according to an application. For example, a number of power device modules and vapor chambers of a power electronics assembly of the present disclosure may be in the range of 1 power device module and 1 vapor chamber to approximately 50 power device modules and 50 vapor chambers and any integer number therebetween. A number of power device modules may also be greater or less than a number of vapor chambers, for example, one or more vapor chambers may be coupled to a corresponding two or more power device modules.

In an example, at least one of the vapor chambers 560 may include an upper wall 562 and a lower wall 564 that define a sealed chamber 566 that contains a second working fluid, such as water. The vapor chamber 560 may also include a plurality of spacers 568, such as metal columns, that structurally support and separate the upper wall 562 and lower wall 564. The vapor chambers 560 may be formed from one or more materials, such as Al, AlSiC, Cu, and/or other materials.

In an example, the baseplate 540 is mechanically attached, e.g., by brazing or friction stir welding, to the vapor chambers 560. For example, the baseplate 540 may have at least one opening 556 having a shape or dimension that is complementary to a shape or dimension of a corresponding vapor chamber 560 disposed in the opening. An inner wall of the baseplate that defines the opening 556 may be mechanically attached to an outer extent or outer perimeter of the corresponding vapor chamber 560, for example, by brazing or friction stir weld.

In an example, the vapor chambers 560 may be disposed in the baseplate 540, in an example, the baseplate 540 may extend from the vapor chambers 560. In an example, the lower walls 564 of the vapor chambers 560 may each partially define the interior volume 544 of the heat sink 502 and may come into direct contact with the first working fluid. The baseplate 540 may have a thickness extending between the upper surface 550 and the lower surface 552 of the baseplate. At least one of the vapor chambers 560 may have a height extending between the upper wall 562 and the lower wall 564 of the vapor chamber. In an example, the thickness of the baseplate 540 may be substantially the same as, or approximately equal to, the height of at least one of the vapor chambers 560. In an example, the upper surface 550 of the baseplate 540 may be substantially aligned with an upper surface of the upper wall 562 of at least one of the vapor chambers 560. In an example, the lower surface 552 of the baseplate 540 may be substantially aligned with a lower surface of the lower wall 564 of at least one of the vapor chambers 560. In an example the thickness of the baseplate 540 may be different than the height of at least one of the vapor chambers 560. In an example, the upper surface of the upper wall 562 and/or the lower surface of the lower wall 564 of at least one of the vapor chambers 560 may be offset from, e.g., may be recessed with respect to, or stand proud of, the upper surface 550 and/or the lower surface 552 of the baseplate 540.

At least one of the vapor chambers 560 may be configured to be attached, e.g., directly attached to, a power device module such as example power device modules 510. In an example, the upper wall 562 of a given vapor chamber 560 may be coupled to a lower metal layer of a corresponding one of the DBM substrates 522, for example, by a solder layer. In some examples, the DBM substrates 522 may be directly coupled to a corresponding one of the vapor chambers 560 by welding, brazing, soldering, and/or thermally coupled by a thermal interface material. In some examples an additional layer, e.g., an additional metal layer, may be disposed between one or more of the DBM substrates 522 and a corresponding one of the vapor chambers 560.

At least one of the vapor chambers 560 includes the upper wall 562 and the lower wall 564 that define the sealed chamber 566 that contains the second working fluid. The vapor chambers 560 are phase changing cooling components where the second working fluid continuously undergoes a phase change during a heat transfer process. For example, the sealed chamber 566 may be a vacuum-sealed chamber and the vapor chamber 560 may contain a wick structure, e.g., a sintered, grooved, or mesh wick structure (not illustrated) that lines interior surfaces of the sealed chamber 566. The wick structure may contain, e.g., be saturated with, the second working fluid. A portion of the second working fluid located adjacent the inner surface of the upper wall 562 may be configured to extract heat from a given power device module 510 coupled to the upper wall of the vapor chamber. The extracted heat may cause the second working fluid to undergo a phase change, transitioning the second working fluid from a liquid phase to a vapor phase, thereby causing a mass transfer of the second working fluid from the wick structure of the upper wall 562 to the interior space of the sealed chamber 566. The vapor-state working fluid may then move towards and contact the relatively-cooler lower wall 564, which may be at a lower temperature than the upper wall 562. The relatively lower temperature of the lower wall 564 causes the second working fluid to condense from the vapor phase back to a liquid phase, also resulting in a transfer of thermal energy, e.g., the latent heat of vaporization of the second working fluid, to the lower wall 564. The released thermal energy may then be transferred through the lower wall 564 to the first working fluid in the interior volume 544 of the heat sink 502. The condensed second working fluid on the lower wall 564 of the sealed chamber 566 can then return to the inner surface of the upper wall 562, e.g., by capillary action through the wick structure, to be vaporized again by the heat dissipated from the power device module 510.

The baseplate 540 has an upper surface 550 and a lower surface 552 and in the illustrated example, at least one pin fin array 554 is coupled to and extends from the lower surface 552 of the baseplate. The pin fin array 554 and the baseplate 540 may be a unitary member, for example the pin fin array 554 may be formed by removing material, e.g., machining, a lower surface of the baseplate. In an example the pin fin array 554 may be formed by joining the pin fins to the baseplate 540 by a joining process, such as welding, brazing or soldering.

Similarly, at least one of the vapor chambers 560 may have a lower wall 564 and in the illustrated example, at least one vapor chamber 560 may include a pin fin array 580 that is coupled to and extends from the lower wall 564. The pin fin array 580 and the lower wall 564 of a corresponding vapor chamber 560 may be a unitary member, for example the pin fin array 580 may be formed by removing material, e.g., machining, a lower wall 564. In an example the pin fin array 580 may be formed by joining the pin fins to the lower wall 564 of a vapor chamber 560 by a joining process, such as welding, brazing or soldering.

The pin fin arrays 554 and 580 may have a plurality of characteristics, including, for example, a cross-sectional shape (e.g., diamond, circle, oval, oblong, triangle, etc.), a cross-sectional size, a material type, a thermal conductivity, and a pin-to-pin spacing. Characteristics of the pin fin arrays 554, 580 may also include a length of the pin fins and a corresponding space or gap between an end of the pin fins and an inner wall of the housing 542. A space or gap between ends of the pin array 554 or 580 and the inner wall of the housing 542 may form a bypass flowpath, e.g. bypass flowpath 558, which allows a portion of the first working fluid to bypass the corresponding pin fins.

The pin fin array 554 may include one or more sections, for example, a plurality of sections 554a, 554b, 554c and 554d. One or more sections, e.g., sections 554b and 554c, may be located between ones of the vapor chambers 560 and sections 554a and 554d may be located between a vapor chamber 560 and the working-fluid inlet 546 or working-fluid outlet 548.

Similarly, one or more characteristics of the pin fin arrays 580 extending from vapor chambers 560 may be different from one or more characteristics of pin fin array 554. In the illustrated example, at least one of a length, a cross sectional area, and a pin-to-pin spacing of pin fin array 580 may be different than pin fin array 554. For example, pin fin array 580 may be longer, have pins with a smaller cross sectional area, and/or a smaller pin-to-pin spacing, which may increase a heat transfer from vapor chambers 560 as compared to a pin fin array with characteristics similar to pin fin array 554. The pin fins of pin fin array 554 may be shorter than the pin fins of pin fin array 580 and define the bypass flowpath 558.

In addition, any one or more characteristics of a given one of the sections of the pin fin arrays 554 may be different than another one of the sections of the pin fin arrays 554. For example, a cross-sectional shape, a cross sectional size, a material type, a thermal conductivity, a pin-to-pin spacing, or a pin fin length of a pin-fin array section located between vapor chambers, e.g., pin-fin-array section 554b or 554c may be different than a pin-fin array section located between the working-fluid inlet 546 or working-fluid outlet 548 and a vapor chamber 560, e.g., pin-fin-array section 554a or 554d. By way of non-limiting example, a length or pin-to-pin spacing of pin-fin-array section 554a or 554d may be different than pin-fin-array section 554b or 554c.

The foregoing is merely provided by way of example. In an example any one or more characteristics of a pin fin array or section of a pin fin array may be different from another pin fin array or section of a pin fin array of power electronics assembly 500.

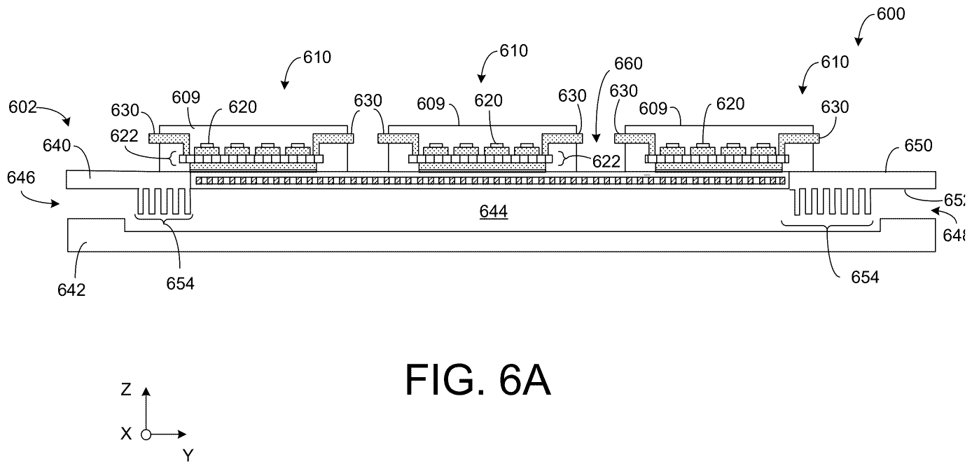

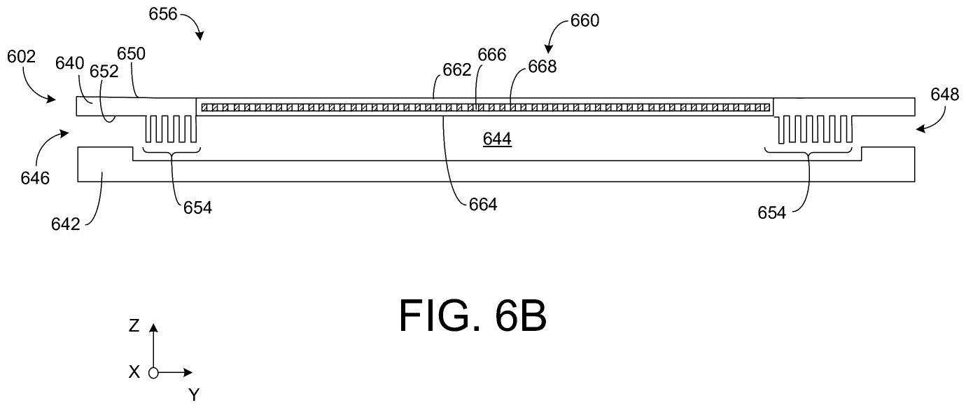

FIG. 6A is a cross-sectional side view of an example implementation of a power electronics assembly 600 that includes a plurality, e.g., three power device modules 610 coupled to a heat sink 602. FIG. 6B is a cross-sectional side view of the heat sink 602 of the power electronics assembly 600.

Referring to FIGS. 6A and 6B, in the illustrated example, the power device modules 610 are each disposed in a casing 609 and include a plurality, e.g., four, semiconductor die 620 (only one labeled) disposed on a substrate, e.g., a DBM substrate 622. Pins 630 extend from the power device modules 610 for electrical connection of a power device module to other components.

In the illustrated example, the heat sink 602 is a liquid cooled heat sink that includes a baseplate 640 that is coupled to a housing 642. The baseplate 640 and housing 642 define an interior volume 644 that is configured for a first working fluid, such as, for example, a water-ethylene glycol mixture, to pass therethrough to transfer thermal energy from the power device modules 610 to the first working fluid. The heat sink 602 also includes a working-fluid inlet 646 and a working-fluid outlet 648 for transfer of the first working fluid into and out of the heat sink.

The baseplate 640 has an upper surface 650 and a lower surface 652 and in the illustrated example, at least one pin fin array 654 is coupled to and extends from the lower surface 652 of the baseplate. The pin fin array 654 and the baseplate 640 may be a unitary member, for example the pin fin array 654 may be formed by removing material, e.g., machining, a lower surface of the baseplate. In an example the pin fin array 654 may be formed by joining the pin fins to the baseplate 640 by a joining process, such as welding, brazing or soldering.

In the illustrated example, the heat sink 602 also includes at least one vapor chamber 660 that is coupled to at least one of the power device modules 610 and the baseplate 640 for transferring thermal energy from the corresponding power device module to the first working fluid in the interior volume 644. In the illustrated example, power electronics assembly 600 includes one vapor chamber 660, which is coupled to a plurality of power device modules 610 of the power electronics assembly 600. For purposes of illustration, example power electronics assembly 600 includes three power device modules 610 and one vapor chamber 660. As will be appreciated, the number of power device modules and vapor chambers that may be coupled to a heat sink, such as heat sink 602, may vary according to an application. For example, a number of power device modules and vapor chambers of a power electronics assembly of the present disclosure may be in the range of 1 power device module and 1 vapor chamber to approximately 50 power device modules and 50 vapor chambers and any integer number therebetween. A number of power device modules may also be greater or less than a number of vapor chambers, for example, one or more vapor chambers may be coupled to a corresponding two or more power device modules.

In an example, the vapor chamber 660 includes an upper wall 662 and a lower wall 664 that define a sealed chamber 666 that contains a second working fluid, such as water. The vapor chamber 660 may also include a plurality of spacers 668, such as metal columns, that structurally support and separate the upper wall 662 and lower wall 664. The vapor chamber 660 may be formed from one or more materials, such as Al, AlSiC, Cu, and/or other materials.

In an example, the baseplate 640 is mechanically attached, e.g., by brazing or friction stir welding, to the vapor chamber 660. For example, the baseplate 640 may have at least one opening 656 having a shape or dimension that is complementary to a shape or dimension of vapor chamber 660 disposed in the opening. An inner wall of the baseplate that defines the opening 656 may be mechanically attached to an outer extent or outer perimeter of the corresponding vapor chamber 660, for example, by brazing or friction stir weld.

In an example, the vapor chamber 660 may be disposed in the baseplate 640, in an example, the baseplate 640 may extend from the vapor chamber 660. In an example, the lower wall 664 of the vapor chamber 660 may partially define the interior volume 644 of the heat sink 602 and may come into direct contact with the first working fluid. The baseplate 640 may have a thickness extending between the upper surface 650 and the lower surface 652 of the baseplate. The vapor chamber 660 may have a height extending between the upper wall 662 and the lower wall 664 of the vapor chamber. In an example, the thickness of the baseplate 640 may be substantially the same as, or approximately equal to, the height of the vapor chamber 660. In an example, the upper surface 650 of the baseplate 640 may be substantially aligned with an upper surface of the upper wall 662 of the vapor chamber 660. In an example, the lower surface 652 of the baseplate 640 may be substantially aligned with a lower surface of the lower wall 664 of the vapor chamber 660. In an example the thickness of the baseplate 640 may be different than the height of the vapor chamber 660. In an example, the upper surface of the upper wall 662 and/or the lower surface of the lower wall 664 of the vapor chamber 660 may be offset from, e.g., may be recessed with respect to, or stand proud of, the upper surface 650 and/or the lower surface 652 of the baseplate 640.

The vapor chamber 660 may be configured to be attached, e.g., directly attached to, a power device module such as example power device modules 610. In an example, the upper wall 662 of vapor chamber 660 may be coupled to a lower metal layer of a corresponding one of the DBM substrates 622, for example, by a solder layer. In some examples, the DBM substrates 622 may be directly coupled to the vapor chamber 660 by welding, brazing, soldering, and/or thermally coupled by a thermal interface material. In some examples an additional layer, e.g., an additional metal layer, may be disposed between one or more of the DBM substrates 622 and the vapor chamber 660.

The vapor chamber 660 includes the upper wall 662 and the lower wall 664 that define the sealed chamber 666 that contains the second working fluid. The vapor chamber 660 is a phase changing cooling component where the second working fluid continuously undergoes a phase change during a heat transfer process. For example, the sealed chamber 666 may be a vacuum-sealed chamber and the vapor chamber 660 may contain a wick structure, e.g., a sintered, grooved, or mesh wick structure (not illustrated) that lines interior surfaces of the sealed chamber 666. The wick structure may contain, e.g., be saturated with, the second working fluid. A portion of the second working fluid located adjacent the inner surface of the upper wall 662 may be configured to extract heat from a given power device module 610 coupled to the upper wall of the vapor chamber. The extracted heat may cause the second working fluid to undergo a phase change, transitioning the second working fluid from a liquid phase to a vapor phase, thereby causing a mass transfer of the second working fluid from the wick structure of the upper wall 662 to the interior space of the sealed chamber 666. The vapor-state working fluid may then move towards and contact the relatively-cooler lower wall 664, which may be at a lower temperature than the upper wall 662. The relatively lower temperature of the lower wall 664 causes the second working fluid to condense from the vapor phase back to a liquid phase, also resulting in a transfer of thermal energy, e.g., the latent heat of vaporization of the second working fluid, to the lower wall 664. The released thermal energy may then be transferred through the lower wall 664 to the first working fluid in the interior volume 644 of the heat sink 602. The condensed second working fluid on the lower wall 664 of the sealed chamber 666 can then return to the inner surface of the upper wall 662, e.g., by capillary action through the wick structure, to be vaporized again by the heat dissipated from the power device module 610.

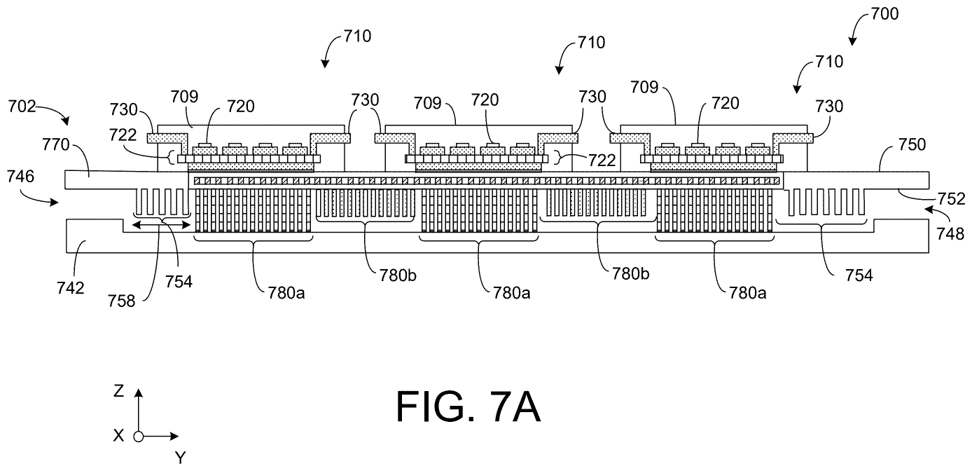

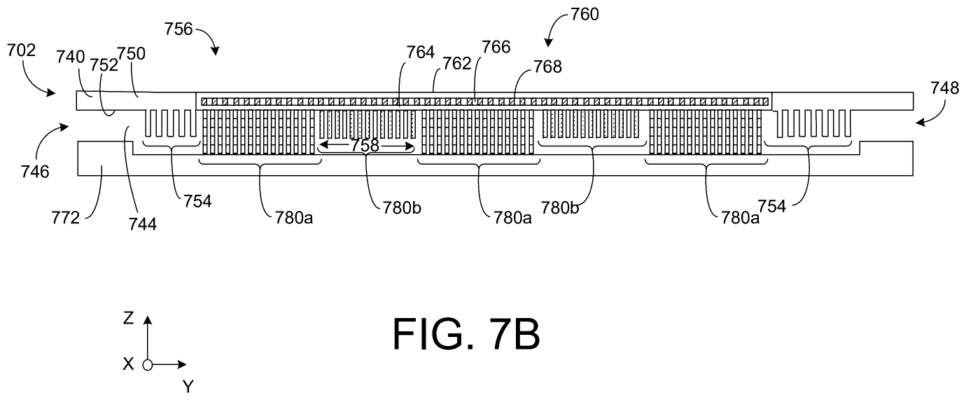

FIG. 7A is a cross-sectional side view of an example implementation of a power electronics assembly 700 that includes a plurality, e.g., three power device modules 710 coupled to a heat sink 702. FIG. 7B is a cross-sectional side view of the heat sink 702 of the power electronics assembly 700.

Referring to FIGS. 7A and 6B, in the illustrated example, the power device modules 710 are each disposed in a casing 709 and include a plurality, e.g., four, semiconductor die 720 (only one labeled) disposed on a substrate, e.g., a DBM substrate 722. Pins 730 extend from the power device modules 710 for electrical connection of a power device module to other components.

In the illustrated example, the heat sink 702 is a liquid cooled heat sink that includes a baseplate 740 that is coupled to a housing 742. The baseplate 740 and housing 742 define an interior volume 744 that is configured for a first working fluid, such as, for example, a water-ethylene glycol mixture, to pass therethrough to transfer thermal energy from the power device modules 710 to the first working fluid. The heat sink 702 also includes a working-fluid inlet 746 and a working-fluid outlet 748 for transfer of the first working fluid into and out of the heat sink.

In the illustrated example, the heat sink 702 also includes at least one vapor chamber 760 that is coupled to at least one of the power device modules 710 and the baseplate 740 for transferring thermal energy from the corresponding power device module to the first working fluid in the interior volume 744. In the illustrated example, power electronics assembly 700 includes one vapor chamber 760, which is coupled to a plurality of power device modules 710 of the power electronics assembly 700. For purposes of illustration, example power electronics assembly 700 includes three power device modules 710 and one vapor chamber 760. As will be appreciated, the number of power device modules and vapor chambers that may be coupled to a heat sink, such as heat sink 702, may vary according to an application. For example, a number of power device modules and vapor chambers of a power electronics assembly of the present disclosure may be in the range of 1 power device module and 1 vapor chamber to approximately 50 power device modules and 50 vapor chambers and any integer number therebetween. A number of power device modules may also be greater or less than a number of vapor chambers, for example, one or more vapor chambers may be coupled to a corresponding two or more power device modules.

In an example, the vapor chamber 760 includes an upper wall 762 and a lower wall 764 that define a sealed chamber 766 that contains a second working fluid, such as water. The vapor chamber 760 may also include a plurality of spacers 768, such as metal columns, that structurally support and separate the upper wall 762 and lower wall 764. The vapor chamber 760 may be formed from one or more materials, such as Al, AlSiC, Cu, and/or other materials.

In an example, the baseplate 740 is mechanically attached, e.g., by brazing or friction stir welding, to the vapor chamber 760. For example, the baseplate 740 may have at least one opening 756 having a shape or dimension that is complementary to a shape or dimension of vapor chamber 760 disposed in the opening. An inner wall of the baseplate that defines the opening 756 may be mechanically attached to an outer extent or outer perimeter of the corresponding vapor chamber 760, for example, by brazing or friction stir weld.

In an example, the vapor chamber 760 may be disposed in the baseplate 740, in an example, the baseplate 740 may extend from the vapor chamber 760. In an example, the lower wall 764 of the vapor chamber 760 may partially define the interior volume 744 of the heat sink 702 and may come into direct contact with the first working fluid. The baseplate 740 may have a thickness extending between the upper surface 750 and the lower surface 752 of the baseplate. The vapor chamber 760 may have a height extending between the upper wall 762 and the lower wall 764 of the vapor chamber. In an example, the thickness of the baseplate 740 may be substantially the same as, or approximately equal to, the height of the vapor chamber 760. In an example, the upper surface 750 of the baseplate 740 may be substantially aligned with an upper surface 770 of the upper wall 762 of the vapor chamber 760. In an example, the lower surface 752 of the baseplate 740 may be substantially aligned with a lower surface 772 of the lower wall 764 of the vapor chamber 760. In an example the thickness of the baseplate 740 may be different than the height of the vapor chamber 760. In an example, the upper surface 770 of the upper wall 762 and/or the lower surface 772 of the lower wall 764 of the vapor chamber 760 may be offset from, e.g., may be recessed with respect to, or stand proud of, the upper surface 750 and/or the lower surface 752 of the baseplate 740.

The vapor chamber 760 may be configured to be attached, e.g., directly attached to, a power device module such as example power device modules 710. In an example, the upper wall 762 of vapor chamber 760 may be coupled to a lower metal layer of a corresponding one of the DBM substrates 722, for example, by a solder layer. In some examples, the DBM substrates 722 may be directly coupled to the vapor chamber 760 by welding, brazing, soldering, and/or thermally coupled by a thermal interface material. In some examples an additional layer, e.g., an additional metal layer, may be disposed between one or more of the DBM substrates 722 and the vapor chamber 760.

The vapor chamber 760 includes the upper wall 762 and the lower wall 764 that define the sealed chamber 766 that contains the second working fluid. The vapor chamber 760 is a phase changing cooling component where the second working fluid continuously undergoes a phase change during a heat transfer process. For example, the sealed chamber 766 may be a vacuum-sealed chamber and the vapor chamber 760 may contain a wick structure, e.g., a sintered, grooved, or mesh wick structure (not illustrated) that lines interior surfaces of the sealed chamber 766. The wick structure may contain, e.g., be saturated with, the second working fluid. A portion of the second working fluid located adjacent the inner surface of the upper wall 762 may be configured to extract heat from a given power device module 710 coupled to the upper wall of the vapor chamber. The extracted heat may cause the second working fluid to undergo a phase change, transitioning the second working fluid from a liquid phase to a vapor phase, thereby causing a mass transfer of the second working fluid from the wick structure of the upper wall 762 to the interior space of the sealed chamber 766. The vapor-state working fluid may then move towards and contact the relatively-cooler lower wall 764, which may be at a lower temperature than the upper wall 762. The relatively lower temperature of the lower wall 764 causes the second working fluid to condense from the vapor phase back to a liquid phase, also resulting in a transfer of thermal energy, e.g., the latent heat of vaporization of the second working fluid, to the lower wall 764. The released thermal energy may then be transferred through the lower wall 764 to the first working fluid in the interior volume 744 of the heat sink 702. The condensed second working fluid on the lower wall 764 of the sealed chamber 766 can then return to the inner surface of the upper wall 762, e.g., by capillary action through the wick structure, to be vaporized again by the heat dissipated from the power device module 710.

The baseplate 740 has an upper surface 750 and a lower surface 752 and in the illustrated example, at least one pin fin array 754 is coupled to and extends from the lower surface 752 of the baseplate. The pin fin array 754 and the baseplate 740 may be a unitary member, for example the pin fin array 754 may be formed by removing material, e.g., machining, a lower surface of the baseplate. In an example the pin fin array 754 may be formed by joining the pin fins to the baseplate 740 by a joining process, such as welding, brazing or soldering.

Similarly, the vapor chamber 760 may have a lower wall 764 and in the illustrated example, a pin fin array 780 that is coupled to and extends from the lower wall 764. The pin fin array 780 and the lower wall 764 of a corresponding vapor chamber 760 may be a unitary member, for example the pin fin array 780 may be formed by removing material, e.g., machining, a lower wall 764. In an example the pin fin array 780 may be formed by joining the pin fins to the lower wall 764 of a vapor chamber 760 by a joining process, such as welding, brazing or soldering.

The pin fin arrays 754 and 780 may have a plurality of characteristics, including, for example, a cross-sectional shape (e.g., diamond, circle, oval, oblong, triangle, etc.), a cross-sectional size, a material type, a thermal conductivity, and a pin-to-pin spacing. Characteristics of the pin fin arrays 754, 780 may also include a length of the pin fins and a corresponding space or gap between an end of the pin fins and an inner wall of the housing 742. A space or gap between ends of the pin array 754 or 780 and the inner wall of the housing 742 may form a bypass flowpath, e.g. bypass flowpath 758, which allows a portion of the first working fluid to bypass the corresponding pin fins.

The pin fin array 780 extending from vapor chamber 760 may include one or more sections, for example, a plurality of sections 780a and 780b, where sections 780a are substantially aligned with a given one of power device modules 710 and sections 780b are located between the power device modules 710. One or more characteristics of the sections 780a aligned with the power device modules 710 may be different from one or more characteristics of sections 780b located between the power device modules 710. In the illustrated example, at least one of a length, a cross-sectional area, and a pin-to-pin spacing of section 780a may be different than section 780b. For example, pin fins of section 780a may be longer, have pins with a smaller cross-sectional area, and/or a smaller pin-to-pin spacing, which may increase a heat transfer from portions of vapor chamber 760 where power device modules 710 are located as compared to a pin fin array with characteristics similar to section 780b.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Silicon Carbide (SiC), Gallium Arsenide (GaAs), Gallium Nitride (GaN), and/or so forth.

In example implementations, more than one semiconductor die can be included in the implementations described herein. In some implementations, different semiconductor die (when more than one semiconductor die is included in some of the implementations) can be fabricated using different semiconductor substrates (e.g., a silicon carbide (SiC) substrate, a silicon (Si) substrate, a gallium nitride (GaN) substrate). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

In example implementations, a first semiconductor die may be connected to a second of the semiconductor die, for example, by an electrical connection (e.g., a wire bond, an electrical clip) extending directly from the first die to the second die, or connected through a trace formed in the first conductive layer (e.g., a metal layer) of an electronic power substrate. The first of the plurality of semiconductor die may be also connected to lead frame posts by electrical connections such as wirebonds or clips.

In example implementations, a package (e.g., a power module) can be a hybrid device package that includes a semiconductor die or a plurality of semiconductor die that are integrated onto to a unifying electronic power substrate (e.g., a ceramic substrate, a DBM or DBC substrate, an AMB substrate). In some implementations, multiple semiconductor devices (e.g., can be fabricated on the same substrate such as a SiC substrate) suitable for high power applications.

In some implementations, the DBM substrate (e.g., direct bonded copper (DBC)) can include an insulating layer disposed between a first metal layer and a second metal layer. The insulating layer can be, for example, a ceramic layer. In some implementations, the insulating layer can be or can include, for example, a ceramic material such as alumina (Al₂O₃) or aluminum nitride (AlN)).

In some implementations, a DBM substrate can be formed by bonding one or more of the metal layers (e.g., first metal layer, second metal layer) to the insulating layer. In some implementations, one or more of the metal layers can be bonded to the insulating layer using, for example, a high-temperature process.

In some implementations, the first metal layer and/or the second metal layer of the DBM substrate can be or can function as a heat sink. In some implementations, the first metal layer and/or the second metal layer can be coupled to a heat sink. In some implementations, at least a portion of one or more of the first metal layer or the second metal layer can be exposed through a molding material.

In some implementations, the first metal layer and/or the second metal layer of the DBM substrate can be or can include a patterned metal layer including one or more electrically conductive traces. In some implementations, the first metal layer and/or the second metal layer can be or can include a patterned layer configured to form one or more electrical circuits, one or more conductive blind and/or through vias, and/or so forth.

In some implementations, soldering can be, or can include, a process of joining two surfaces (e.g., metal surfaces) together using a molten filler metal (e.g., metal alloy, Tin (Sn), Lead (Pb), Silver (Ag), Copper (Cu)) that can be referred to as a solder.

In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature.

In some implementations, one or more of the components described herein can be coupled using materials such as, for example, a solder, a sintering (e.g., silver, copper) material, and/or other metal-to-metal type bonding materials.

In some implementations, a coupling of components can be performed using, for example, a solder process, a sintering process (e.g., a silver sintering process, a copper sintering process), and/or other metal-to-metal type bonding processes.

The semiconductor device packages described herein can include a plurality of signal terminals. The plurality of signal terminals can be power terminals, input signal terminals, output signal terminals, and so forth. In some implementations, the plurality of signal terminals can be included in a leadframe. In some implementations, a leadframe can include any type of conductive portion of a package (e.g., conductive portion, conductive terminal) that can provide an external connection point from a package. Accordingly, a leadframe can be referred to as a conductive portion of a package or assembly. In some implementations, one or more portions of a leadframe can be coupled to a pad (e.g., a bond pad) on at least a portion of a DBM substrate and/or a semiconductor die.

In some implementations, a molding compound (e.g., molding material or compound, an encapsulation material) can be or can include a non-conducting layer/material. In some implementations, the molding compound is a non-conducting material, such as an epoxy, which can be formed (applied, etc.) using a transfer molding process or a compression molding process. In some implementations, the molding compound can include a separate plastic housing that is included in the semiconductor device assembly.

One or more wire bonds, which can be included in at least some of the implementations described herein, can be replaced with a conductive component. For example, in some implementations, one or more wire bonds can be replaced with a conductive clip. The conductive clip can be coupled to another component (e.g., an attach pad, a leadframe, a semiconductor die, and/or so forth) using, for example, a solder (e.g., a soldering process), a sintered coupling (e.g., a sintering process), a weld, and/or so forth. In some implementations, one or more wire bonds and/or clips can function as an input and/or output power terminal, a signal terminal, a power terminal, and/or so forth.

In some implementations, one or more semiconductor die associated with the implementations described herein can be embedded within a layer (rather than surface mounted). For example, one or more semiconductor die can be disposed within a recess (also can be, or can be referred to as a cavity) of a layer (e.g., a substrate, a printed circuit board, a conductive layer, an insulating layer).

In some implementations, a module (e.g., a package including a semiconductor device) can be included in another module. The module can be referred to as a package. For example, one or more modules can be one or more sub modules included within another module. In other words, a first module can be included as a sub module within a second module.

In some implementations, a spacer material can be an epoxy, a silicone adhesive, a conductive material, a non-conductive material, an organic material, a semiconductor material, a metal alloy, a metal foam, a phase change material, etc.

While certain features of the described implementations have been illustrated as described herein, many modifications, substitutions, changes and equivalents will now occur to those skilled in the art. For instance, features illustrated with respect to one implementation can, where appropriate, also be included in other implementations. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A heat sink, comprising:
a vapor chamber;
a baseplate extending from the vapor chamber; and
a housing coupled to the baseplate;
wherein the housing and the baseplate define an interior volume configured for a first working fluid to pass therethrough to transfer thermal energy from the baseplate and the vapor chamber to the first working fluid.

2. The heat sink of claim 1, wherein the vapor chamber includes an upper wall and a lower wall that define a sealed chamber that contains a second working fluid, wherein the upper wall is configured to be coupled to a power device module and the lower wall partially defines the interior volume and comes into direct contact with the first working fluid.

3. The heat sink of claim 2, wherein the baseplate is joined to the vapor chamber at a perimeter of the vapor chamber.

4. The heat sink of claim 2, wherein the baseplate includes an opening, wherein the vapor chamber is disposed in the opening and coupled to the baseplate.

5. The heat sink of claim 2, wherein a thickness of the baseplate is approximately equal to a height of the vapor chamber.

6. The heat sink of claim 2, further comprising a vapor chamber pin fin array extending from the lower wall of the vapor chamber.

7. The heat sink of claim 6, further comprising a baseplate pin fin array extending from a lower surface of the baseplate, wherein at least one characteristic of the vapor chamber pin fin array is different than the baseplate pin fin array.

8. The heat sink of claim 7, wherein the at least one characteristic is a length, a cross-sectional area, a thermal conductivity, or a pin-to-pin spacing.

9. The heat sink of claim 6, further comprising a baseplate pin fin array extending from a lower surface of the baseplate, wherein a pin fin of the baseplate pin fin array is shorter than a pin fin of the vapor chamber pin fin array and defines a bypass flowpath between the baseplate pin fin array and an inner wall of the housing.

10. A power electronics assembly, comprising:
at least one power device module; and
a heat sink including:
a vapor chamber;
a baseplate extending from the vapor chamber; and
a housing coupled to the baseplate;
wherein the housing and the baseplate define an interior volume configured for a first working fluid to pass therethrough to transfer thermal energy from the baseplate and the vapor chamber to the first working fluid.

11. The power electronics assembly of claim 10, wherein the vapor chamber includes an upper wall and a lower wall that define a sealed chamber that contains a second working fluid, wherein the upper wall is coupled to the at least one power device module and the lower wall partially defines the interior volume and comes into direct contact with the first working fluid.

12. The power electronics assembly of claim 11, wherein the at least one power device module includes a direct bonded metal (DBM) substrate that includes a metal layer, wherein the upper wall of the vapor chamber is directly coupled to the metal layer of the DBM substrate.

13. The power electronics assembly of claim 11, wherein the baseplate is joined to the vapor chamber at a perimeter of the vapor chamber.

14. The power electronics assembly of claim 11, wherein the baseplate includes an opening, wherein the vapor chamber is disposed in the opening and coupled to the baseplate.

15. The power electronics assembly of claim 11, wherein a thickness of the baseplate is approximately equal to a height of the vapor chamber.

16. The power electronics assembly of claim 11, further comprising a vapor chamber pin fin array extending from the lower wall of the vapor chamber.

17. The power electronics assembly of claim 16, further comprising a baseplate pin fin array extending from a lower surface of the baseplate, wherein at least one characteristic of the vapor chamber pin fin array is different than the baseplate pin fin array.

18. The power electronics assembly of claim 17, wherein the at least one characteristic is a length, a cross-sectional area, a thermal conductivity, or a pin-to-pin spacing.

19. The power electronics assembly of claim 16, further comprising a baseplate pin fin array extending from a lower surface of the baseplate, wherein a pin fin of the baseplate pin fin array is shorter than a pin fin of the vapor chamber pin fin array and defines a bypass flowpath between the baseplate pin fin array and an inner wall of the housing.

20. The power electronics assembly of claim 11, wherein the at least one power device module includes a first power device module and a second power device module, wherein the first power device module and the second power device module are coupled to the upper wall of the vapor chamber.

21. The power electronics assembly of claim 20, further comprising a pin fin array extending from the lower wall of the vapor chamber, wherein the pin fin array includes a first section of pin fins aligned with the first power device module, a second section of pin fins aligned with the second power device module, and a third section of pin fins located between the first and second sections of pin fins, wherein at least one characteristic of the third section of pin fins is different than at least one of the first or second sections of pin fins.
